(19) United States
(12) Patent Application Publication
(10) Pub. No.: US 2006/0133559 A1
(43) Pub. Date: Jun. 22, 2006

(54) Programmable fractional N phase locked loop architecture and method

(76) Inventor: Kevin W. Glass, Scottsdale, AZ (US)

Correspondence Address: THE LAW OFFICES OF JOHN C. SCOTT, LLC;C/O PORTFOLIOIP, P. O. BOX 52050, MINNEAPOLIS, MN, 55402, US

(21) Appl. No.: 11/021,455

(22) Filed: Dec. 22, 2004

(51) Int. Cl. H03D 3/24

(52) U.S. Cl. 375/376

(57) ABSTRACT

A fractional N phase locked loop (PLL) includes a programmable digital signal processor (DSP) to perform various processing functions within the PLL. In at least one embodiment, the programmable nature of the DSP allows programs to be modified and/or added to the PLL to support a variety of different applications.

### TECHNICAL FIELD

The invention relates generally to phase locked loops and, more particularly, to fractional N phase locked loops.

### BACKGROUND OF THE INVENTION

Fractional N phase locked loops (PLLs) allow signals to be generated at non-integer multiples of a reference signal frequency. In this way, fractional N PLLs are capable of achieving much finer frequency granularity than are integer N PLLs. Because of this, fractional N PLLs have become a key building block in modern radio communication systems. Fractional N PLLs are typically realized using dedicated, hardwired logic circuits. As the requirements placed on fractional N PLLs become more demanding, the complexity of the logic used to implement them has increased significantly. In addition, these PLL designs are often very narrow in application and are not generally adaptable for use in other applications. There is a need for fractional N PLL designs that are more flexible than designs of the past.

### BRIEF DESCRIPTION OF THE DRAWINGS

FIG. 1 is a block diagram illustrating a prior art fractional N phase locked loop (PLL);

FIG. 2 is a block diagram illustrating an example fractional N PLL in accordance with an embodiment of the present invention;

FIG. 3 is a block diagram illustrating an example fractional N PLL in accordance with another embodiment of the present invention;

FIG. 4 is a block diagram illustrating an example multifunction DSP datapath in accordance with an embodiment of the present invention;

FIG. 5 is a flowchart illustrating an example method for use in synthesizing a phase locked signal in accordance with an embodiment of the present invention; and

FIG. 6 is a flowchart illustrating an example method that may be used to operate a fractional N PLL within a multimode radio in accordance with an embodiment of the present invention.

### DETAILED DESCRIPTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

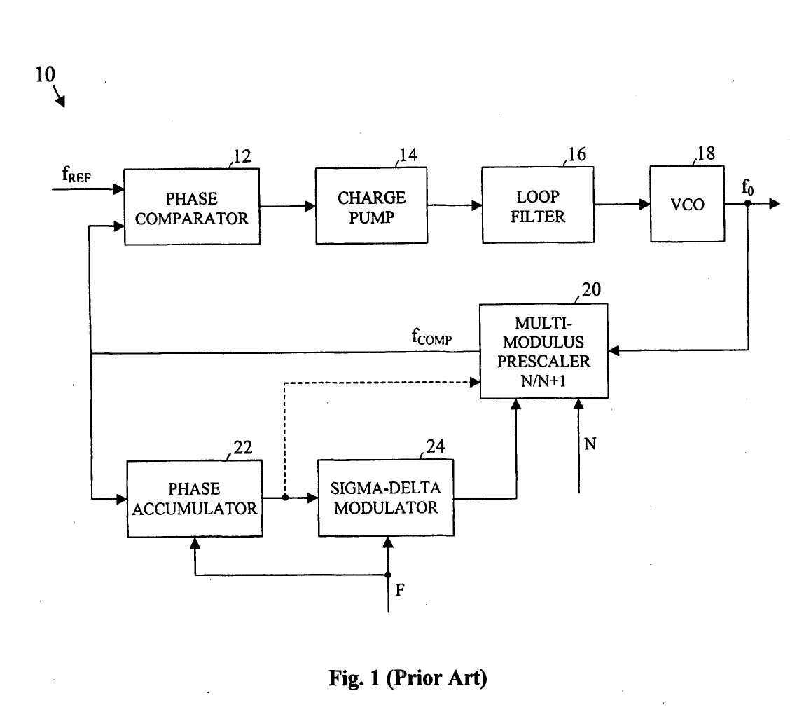

FIG. 1 is a block diagram illustrating a fractional N phase locked loop (PLL) 10 of the prior art. The fractional N PLL 10 is capable of generating an output signal that is phase locked to a reference signal and that has a frequency f₀ that is a non-integer multiple of the frequency of the reference signal f_{REF}. As illustrated in FIG. 1, the PLL 10 includes: a phase comparator 12, a charge pump 14, a loop filter 16, a voltage controlled oscillator (VCO) 18, a multi-modulus prescaler 20, a phase accumulator 22, and a sigma-delta modulator 24. The multi-modulus prescaler 20 is a frequency divider component that is capable of dividing the frequency of a signal by a selected one of a plurality of divisor values. In a dual modulus implementation, for example, the multi-modulus prescaler 20 may switch between two different divisor values (e.g., N and N+1) during operation. Multi-modulus prescalers 20 may also be used that switch between three or more divisor values. When a divisor of N is being used by the multi-modulus prescaler 20, the output frequency f₀ of the PLL 10 will be equal to the product of N and the reference frequency f_{REF}. Likewise, when a divisor of N+1 is being used, the output frequency f₀ of the PLL 10 will be equal to the product of N+1 and the reference frequency f_{REF}. By switching between the two different divisors, a fractional divisor can be achieved, on average, that is between N and N+1. That is, an output frequency f₀ may be achieved that is a product of N+F and the reference frequency f_{REF}, where F is a fraction that is less than 1.

The multi-modulus prescaler 20 receives the output signal of the VCO 18 and frequency divides the signal to achieve a comparison signal having a frequency f_{COMP}. The comparison signal is input into the phase comparator 12 where the phase of the signal is compared to the phase of a reference signal. The output signal of the phase comparator 12 is indicative of the phase difference. For example, in one approach, the output signal of the phase comparator 12 may be a voltage pulse that has a pulse width that is proportional to the phase difference. Other types of signal representation may alternatively be used. The output of the phase comparator 12 is delivered to the charge pump 14 which produces an output current that is directed to the loop filter 16. The loop filter 16 filters and smoothes the current signal, thus converting it into a voltage control signal that is applied to the VCO 18. The voltage level of the voltage control signal controls the frequency f₀ of the output signal of the VCO 18.

The phase accumulator 22 may be used to control when the multi-modulus prescaler 20 switches between divisor values. In one approach, the phase accumulator 22 tracks and accumulates the error between the phase of the comparison signal and the desired phase. When the phase error accumulates to 360 degrees, the phase accumulator 22 may instruct the multi-modulus prescaler 20 to change the divisor from N to N+1. This effectively “swallows” a VCO signal period of 360 degrees and returns the accumulated phase error to zero. After another 360 degrees of phase error is accumulated, the phase accumulator 22 may instruct the multi-modulus prescaler 20 to change the divisor back from N+1 to N, and so on. As mentioned above, the overall effect of this process is an output frequency that is N.F times the reference frequency. A similar technique may be practiced using more than two divisor values.

The fractional N phase locked loop techniques described above may result in the generation of spurious tones within the loop output signal at multiples of the fractional offset frequency. In certain applications, it may be necessary to reduce the level of these spurious tones about the output frequency f₀. The sigma-delta modulator 24 may be used to modulate the phase accumulator value in a manner that randomizes the pulse swallowing timing to move the spurious energy away from the frequency of interest. This allows the spurious energy to be filtered out within, for example, the loop filter 16. Techniques for implementing sigma-delta modulation are well known.

In a typical implementation, the various components of the fractional N PLL 10 of FIG. 1 will be specially designed logic circuits that are capable of performing a single dedicated task. As such, it will often be difficult or impossible to modify or reconfigure a particular PLL for use in a different application. In one aspect of the present invention, some or all of the dedicated functionality within a fractional N PLL is replaced with a programmable digital signal processor (DSP). As is well known, a DSP is a special form of microprocessor that is specifically designed to perform digital signal processing tasks. DSPs are programmable devices that utilize a predefined instruction set and may, therefore, be repeatedly reprogrammed to perform a wide variety of different signal processing tasks. By utilizing a DSP within a fractional N PLL, the PLL may have application in a much wider variety of systems than PLLs of the past. That is, the DSP within the PLL may be programmed differently for use within different systems. In addition, when used within communications applications, the PLL can be used to support a plurality of different radio standards to implement, for example, multimode radio, software defined radio, etc. The programmable PLL may also be used to support reprogramming on the fly for agile radio.

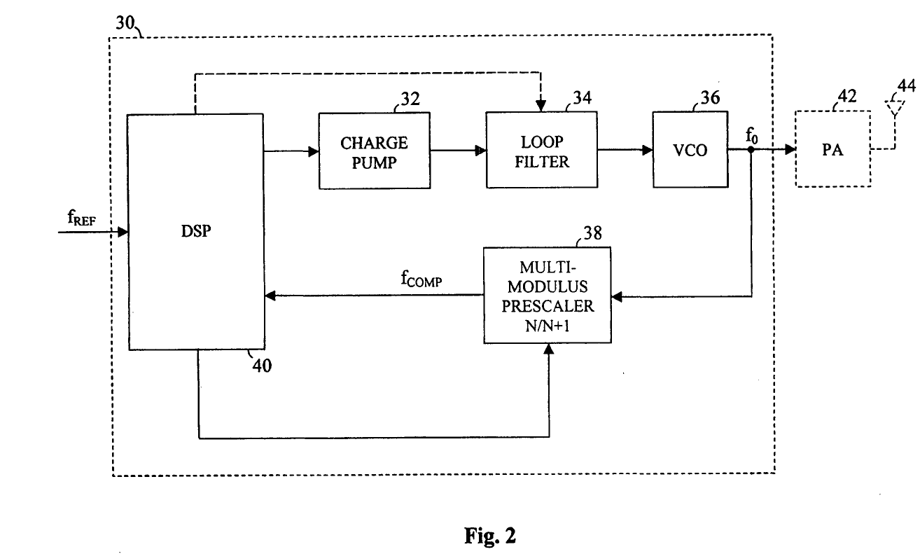

FIG. 2 is a block diagram illustrating an example fractional N PLL 30 in accordance with an embodiment of the present invention. In at least one application, the fractional N PLL 30 may be used in a communications device or system where it is coupled to a power amplifier 42 for amplifying a transmit signal to be transmitted from one or more antennas 44. Many other applications also exist. As illustrated in FIG. 2, the fractional N PLL 30 may include one or more of: a charge pump 32, a loop filter 34, a VCO 36, a multi-modulus prescaler 38, and a digital signal processor (DSP) 40. The charge pump 32, the loop filter 34, the VCO 36, and the multi-modulus prescaler 38 may operate in the same or a similar manner to the corresponding components within FIG. 1. The multi-modulus prescaler 38 may use any number of different divisor values (i.e., two or more). The DSP 40 may be used to, for example, compare the phase of the comparison signal output by the multi-modulus prescaler 38 to the phase of the reference signal and to generate an input signal for the charge pump 32 based on the comparison. In an alternative approach, the charge pump 32 may be removed from the PLL 30 and the DSP 40 may output a signal (e.g., a pulse width modulation (PWM) signal) directly to the input of the loop filter 34. Other techniques may alternatively be used.

The DSP 40 may also be used to generate the control input for the multi-modulus prescaler 38 to control the divisor value used thereby. This function may include, for example, the accumulation of a phase error, as described previously, and the switching of the divisor value when the accumulated phase error reaches a predetermined point (e.g., 360 degrees). In addition, the DSP 40 may be used to implement noise shaping for the PLL 30 to move some or all of the noise energy generated by the switching of the multi-modulus prescaler 38 away from the frequency of interest so that it can be filtered more effectively. The noise shaping may be performed using, for example, sigma-delta modulation techniques or other randomization techniques. In at least one implementation, the DSP 40 may be programmed to modify the bandwidth of the loop filter 34 by sending an appropriate control signal thereto. The loop filter bandwidth may be narrowed by the DSP 40, for example, after lock has been detected for the loop 30. This may enable the PLL 30 to speed up its lock time while maintaining phase noise specifications. In at least one implementation, the function of the multi-modulus prescaler 38 is performed within the DSP 40.

The loop functions that are performed within the DSP 40 are carried out based on program execution within the DSP 40. The capabilities of the PLL 30 may therefore be enhanced by adding to or modifying the programs stored within the system. For example, if a third order sigma-delta modulation routine being used by PLL 30 is not producing adequate phase noise performance, the DSP 40 could be reprogrammed with a fourth order sigma-delta modulation routine. Likewise, if a communication device (e.g., a cellular telephone, a wireless networking device, a pager, etc.) is operating in accordance with a first wireless standard and the user would like to extend operation to use with additional wireless standards, appropriate programming may be added to the DSP 40. In addition to the above, the use of a DSP may also enable more sophisticated processing techniques to be used than are practical using dedicated hardware. Also, in many cases, a DSP will actually reduce the amount of circuitry that is required to implement a fractional N PLL. This is because a DSP can practice programmable hardware reuse that can, for example, use a single multiplier four times rather than supplying four different multipliers to complete the same task Less circuitry will typically result in die area savings and may also reduce power dissipation in a system.

In communications applications, the DSP 40 may be programmed to perform one or more communication related functions. For example, in one implementation, the DSP 40 is programmed to facilitate the performance of direct transmit modulation. In such an implementation, the VCO 36 may be modulated with the required phase of the signal to be transmitted and may directly drive a power amplifier (e.g., PA 42 of FIG. 2). The signal to be transmitted is first translated into polar form having a magnitude and a phase. The phase shifts are introduced to the VCO 36 by modulating the loop feedback count. In addition, the modulation may be pre-distorted to compensate for the loop frequency response. The pre-distortion may be performed in the DSP 40 by filtering the modulation signal in, for example, a finite impulse response (FIR) or infinite impulse response (IIR) filter that has a response that is the inverse of the loop response. In at least one embodiment, pre-emphasis is also performed within the DSP 40 to compensate for the frequency response of the power amplifier. The pre-emphasis may also be performed through digital filtering. Other applications and performance optimizations for a fractional N phase locked loop/synthesizer may also be carried out within the DSP 40. In at least one embodiment, the elements of the fractional N PLL 30 of FIG. 2 are all integrated on a common semiconductor chip. In some other embodiments, discrete components are combined to achieve the PLL 30 (e.g., an of the shelf DSP, etc.). Hybrid embodiments may also be implemented. It should be appreciated that the fractional N PLL architecture of FIG. 2 is merely an example of one possible type of DSP-based PLL arrangement that may be used in accordance with the present invention.

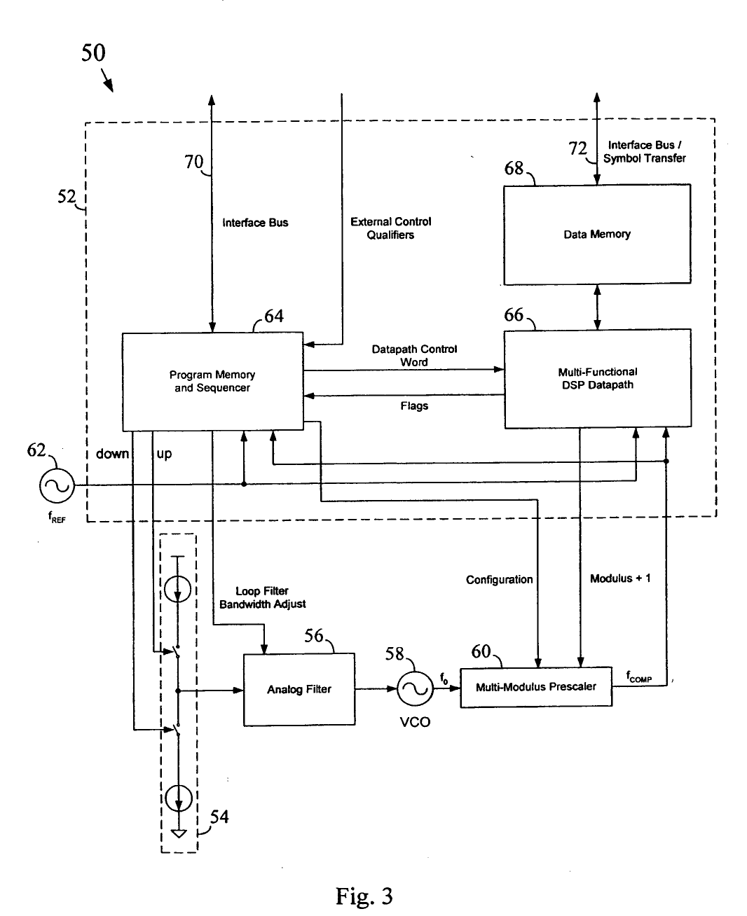

FIG. 3 is a block diagram illustrating an example fractional N PLL 50 in accordance with an embodiment of the present invention. The fractional N PLL 50 includes: a DSP 52, a charge pump 54, a loop filter 56, a VCO 58, and a multi-modulus prescaler 60. The DSP 52 includes: a program memory and sequencer 64, a multi-functional DSP datapath 66, and a data memory 68. The DSP datapath 66 performs the actual processing of data within the DSP 52. The program memory and sequencer 64 stores and executes one or more programs that may be used to, among other things, control processing within the DSP datapath 66. The DSP datapath 66 may include one or more hardware adders and multipliers (and/or other processing elements) to perform the various processing tasks. The program memory and sequencer 64 can source register addresses for the operands to be acted upon, along with the required control signals, to the processing elements within the datapath 66. The DSP datapath 66 may deliver flag signals back to the program memory and sequencer 64 to support the implementation of conditional instructions. Instead of using a program sequencer, the programs executed by the program memory and sequencer 64 could be controlled using a next address field embedded in each instruction. The data memory 68 may store the data to be acted upon within the datapath 66.

In the PLL 50 of FIG. 3, the multi-modulus prescaler 60 divides the frequency of the output signal of the VCO 58 by one of a number of different divisor values to generate a comparison signal. The comparison signal is delivered to an input of the DSP 52. A reference source 62 is coupled to an input of the DSP 52 to supply a reference signal. The DSP 52, under the control of the program memory and sequencer 64, compares the phase of the comparison signal to the phase of the reference signal. The DSP 52 then develops a control signal for delivery to the charge pump 54 based on the comparison. If the frequency of the VCO 58 needs to be increased, the DSP 52 may cause the charge pump 54 to deliver a positive current pulse of the appropriate pulse width to the loop filter 56. If the frequency of the VCO 58 needs to be decreased, the DSP 52 may cause the charge pump 54 to deliver a negative current pulse of the appropriate pulse width to the loop filter 56. Alternatively, the DSP 52 could feed the loop filter 56 directly (using, for example, a PWM output voltage signal). As described previously, the loop filter 56 filters the signal applied thereto to develop the voltage control signal for the VCO 58.

In at least one implementation, the program memory and sequencer 64 may be programmed to deliver configuration parameters to the multi-modulus prescaler 60 to configure the prescaler. Similarly, the program memory and sequencer 64 may be programmed to deliver a bandwidth adjust signal to the loop filter 56 to adjust the bandwidth thereof. This feature may be used to, as discussed previously, reduce the bandwidth of the loop filter after it is determined that lock has been achieved. Furthermore, the program memory and sequencer 64 could also be programmed to perform noise shaping within the DSP datapath 66 to reduce phase noise within an output signal of the PLL 50. Direct transmit modulation routines may also be implemented within the program memory and sequencer 64, with or without modulation pre-distortion and/or preemphasis. Other functions/features may also be implemented within the DSP 52. The DSP 52 may include an interface bus 70 to allow the PLL 50 to be controlled/programmed by a user. Using the interface bus 70, a user would be able to add programs to, or modify programs already resident within, the program memory and sequencer 64. Another interface bus 72 may be provided to allow data to be transferred to/from the data memory 68 (for use in, for example, direct transmit modulation activities, etc.). In at least one implementation, a single interface bus is provided for both programming and data transfer. It should be appreciated that the DSP architecture illustrated in FIG. 3 is merely an example of one possible type of architecture that may be used in accordance with the present invention.

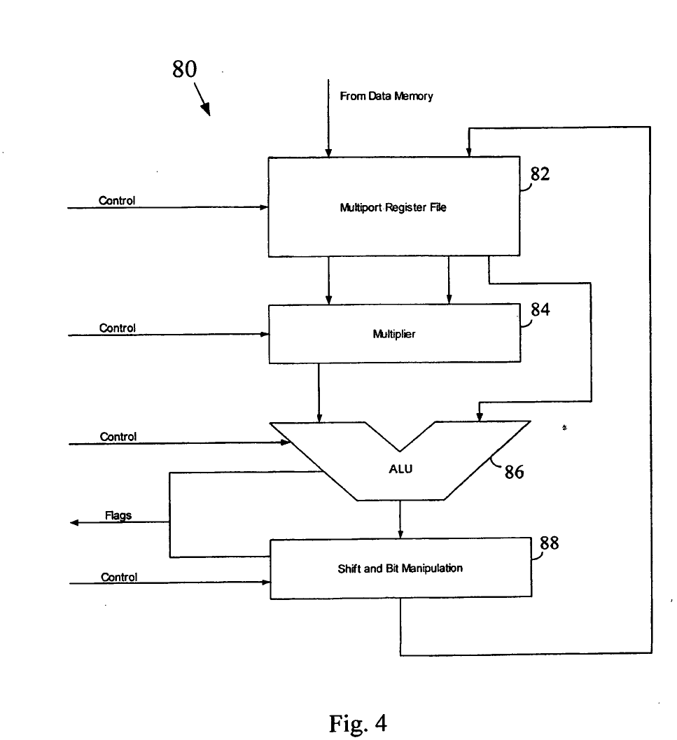

FIG. 4 is a block diagram illustrating an example multifunction DSP datapath 80 in accordance with an embodiment of the present invention. The datapath 80 may be used within, for example, the DSP 52 of the fractional N PLL 50 of FIG. 3 or in PLLs having other architectures. As illustrated, the DSP datapath 80 includes: a multiport register file 82, a multiplier 84, an arithmetic logic unit (ALU) 86, and a shift and bit manipulation unit 88. Each of these components 82, 84, 86, 88 may receive control information from a corresponding control unit (e.g., program memory and sequencer 64 of FIG. 3, etc.). The multiport register file 82 stores the operands to be operated upon by the other elements of the datapath 80. The multiplier 84 is operative for multiplying operands received at the inputs thereof. The ALU 86 carries out arithmetic and logic operations on operands applied thereto. The shift and bit manipulation unit 88 may be used to perform, for example, coding/control operations in conjunction with the ALU 86. In at least one embodiment, for example, the ALU 86 and the shift and bit manipulation unit 88 are used together to implement the sigma/delta modulator. As shown, the ALU 86 and the shift and bit manipulation unit 88 return flags to the corresponding control unit to support the use of conditional instructions.

The DSP datapath 80 may be used to provide any number of different functions for an implementing PLL/synthesizer. For example, the datapath 80 may be used to perform noise shaping in the PLL (e.g., sigma-delta modulation, etc.) to reduce the phase noise generated within the PLL. A typical fully-hardware, third order sigma-delta modulator might consist of three stages that each include an adder and corresponding registers to store values to be fed back for recursive addition. Using the datapath 80, only a single ALU 82 and register file 82 is needed to implement the modulator and software control may be used to provide the appropriate operands and instructions to the units at the appropriate times. In addition, as discussed previously, if a third order sigma-delta modulator is not providing a required phase noise performance, a program implementing a fourth or fifth order sigma-delta modulator may be loaded and used without any change in hardware. Any number of other functions may also be implemented within the datapath 80 with the appropriate software control including, for example, phase modulation, pre-distortion, and/or pre-emphasis for a PLL implementing direct transmit modulation. The hardware re-use feature of the DSP may result in an overall reduction in the amount of circuitry and die area required to implement a PLL. This reduction in circuitry may also provide a corresponding reduction in PLL power consumption. It should be appreciated that the DSP datapath 80 of FIG. 4 is merely illustrative of one datapath architecture that may be used in accordance with the present invention. Other architectures, including much more complex architectures, may alternatively be used. In at least one embodiment, a data path is used that includes two or more multipliers in parallel.

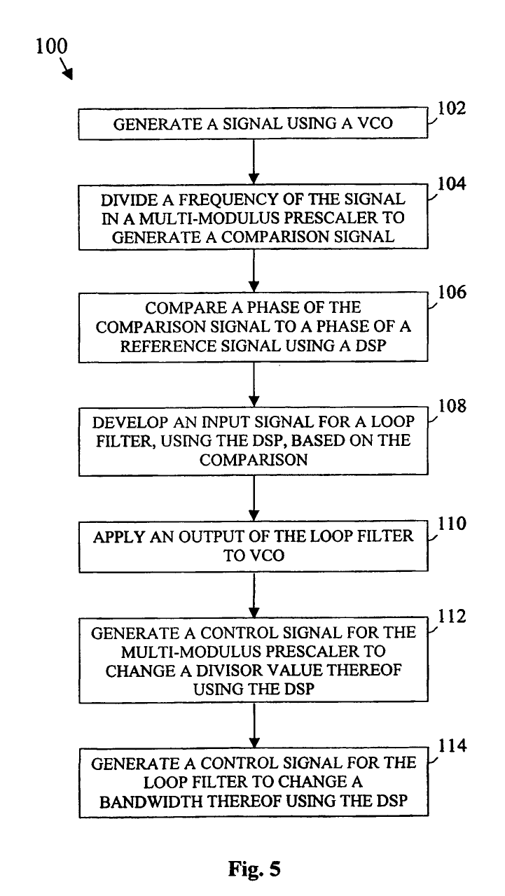

FIG. 5 is a flowchart illustrating an example method 100 for use in synthesizing a phase locked signal in accordance with an embodiment of the present invention. First, a signal is generated within a VCO (block 102). A frequency of the signal is then divided within a multi-modulus prescaler to generate a comparison signal (block 104). Using a DSP, the phase of the comparison signal is then compared to the phase of a reference signal (block 106). An input signal for a loop filter is then developed, using the DSP, based on a result of the comparison (block 108). A charge pump may or may not be used in developing the filter input signal. The output of the loop filter is applied to the VCO as a control signal to control the frequency of the output signal (block 110). At appropriate times, a control signal may be generated by the DSP for the multi-modulus prescaler to change a divisor value being used thereby (block 112). In some embodiments, noise shaping techniques (e.g., sigma delta modulation, etc.) are used during generation of the control signal. At appropriate times, a control signal may also be generated by the DSP for the loop filter to change a bandwidth thereof (block 114). This may be performed, for example, to reduce the bandwidth of the loop after lock has been detected. The bandwidth of the loop filter may also be changed for other reasons. For example, in communications applications such as multimode radio, different loop bandwidths may be appropriate when operating in accordance with different wireless standards.

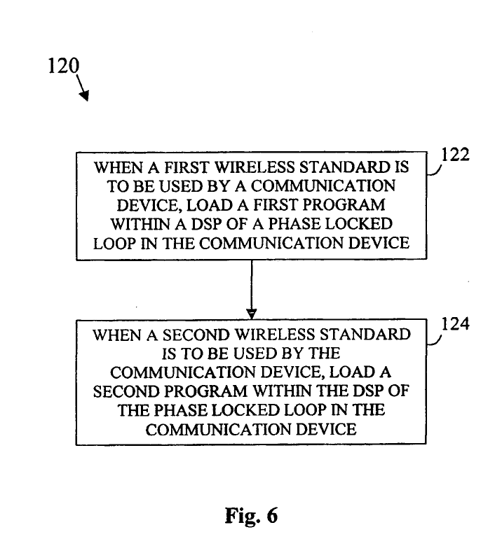

FIG. 6 is a flowchart illustrating an example method 120 that may be used to operate a fractional N phase locked loop within a system implementing multi-mode radio or software defined radio in accordance with an embodiment of the present invention. When a first wireless standard (e.g., IEEE 802.11a) is being used by a communication device, a first program (or programs) that is associated with the first wireless standard is loaded into the program memory of the DSP within the PLL (block 122). The first program may then be executed during operation under the first wireless standard. When the communication device later changes to a second wireless standard (e.g., IEEE 802.11b), a second program (or programs) that is associated with the second wireless standard is loaded into the program memory of the DSP (block 122). The second program may then be executed during operation under the second wireless standard. Any number of wireless standards may be supported in this manner. The programs used for the different wireless standards may control parameters such as: the output frequency of the PLL, the techniques (if any) for performing direct transmit modulation, the number and values of the different divisors to be used by the multi-mode prescalar, the type of noise shaping to be performed, if any (e.g., a second order sigma-delta modulator, a third order sigma-delta modulator, etc.), and/or others.

The techniques and structures of the present invention may be implemented in any of a variety of different forms. For example, in communications applications, features of the invention may be embodied within cellular telephones and other handheld wireless communicators; personal digital assistants having wireless capability; laptop, palmtop, desktop, and tablet computers having wireless capability; pagers; satellite communicators; multimode radios; agile radio; software defined radio; wireless network interface cards (NICs) and other network interface structures; integrated circuits; as instructions and/or data structures stored on machine readable media; and/or in other formats. Examples of different types of machine readable media that may be used include floppy diskettes, hard disks, optical disks, compact disc read only memories (CD-ROMs), magneto-optical disks, read only memories (ROMs), random access memories (RAMs), erasable programmable ROMs (EPROMs), electrically erasable programmable ROMs (EEPROMs), magnetic or optical cards, flash memory, and/or other types of media suitable for storing electronic instructions or data. In at least one form, features of the invention are embodied as a set of instructions that are modulated onto a carrier wave for transmission over a transmission medium. The techniques and structures of the present invention may be used in any application that might benefit from the use of a fractional N PLL and are not limited to use in communications related applications.

In the foregoing detailed description, various features of the invention are grouped together in one or more individual embodiments for the purpose of streamlining the disclosure. This method of disclosure is not to be interpreted as reflecting an intention that the claimed invention requires more features than are expressly recited in each claim. Rather, as the following claims reflect, inventive aspects may lie in less than all features of each disclosed embodiment.

Although the present invention has been described in conjunction with certain embodiments, it is to be understood that modifications and variations may be resorted to without departing from the spirit and scope of the invention as those skilled in the art readily understand. Such modifications and variations are considered to be within the purview and scope of the invention and the appended claims.

What is claimed is:

1. A fractional N phase locked loop comprising:
a voltage controlled oscillator (VCO) to generate an output signal in response to an input control signal;
a loop filter to generate said input control signal of said VCO;
a multi-modulus prescaler to receive said output signal of said VCO and to divide a frequency of said output signal by a variable divisor value to generate a comparison signal; and
a programmable digital signal processor (DSP) to compare a phase of said comparison signal to a phase of a reference signal and to generate an output signal based on said comparison.

2. The phase locked loop of claim 1, further comprising:
a charge pump to receive said output signal of said DSP and to use said output signal to generate an input signal for said loop filter.

3. The phase locked loop of claim 1, wherein:
said output signal of said DSP is delivered to an input of said loop filter.

4. The phase locked loop of claim 1, wherein:
said programmable DSP is to generate a control signal for said multi-modulus prescaler to control said variable divisor value.

5. The phase locked loop of claim 4, wherein:
said programmable DSP is to perform noise shaping during generation of said control signal for said multi-modulus prescaler to move spurious frequencies away from said output frequency of said VCO.

6. The phase locked loop of claim 5, wherein:
said noise shaping includes sigma-delta modulation.

7. The phase locked loop of claim 1, wherein:
said programmable DSP includes a program memory and sequencer to store program instructions and to sequence through said program instructions.

8. The phase locked loop of claim 7, wherein:
said programmable DSP includes a multi-functional DSP datapath to process data in a desired manner, said multi-functional DSP datapath to receive control information from said program memory and sequencer to control the operation thereof.

9. The phase locked loop of claim 1, wherein:
said programmable DSP is to control a bandwidth of said loop filter.

10. The phase locked loop of claim 9, wherein:
said programmable DSP is to reduce a bandwidth of said loop filter after lock has been detected in said phase locked loop.

11. A communication device comprising:
a power amplifier to drive at least one antenna; and
a fractional N phase locked loop comprising:
a voltage controlled oscillator (VCO) to generate an output signal in response to an input control signal;
a loop filter to generate said input control signal of said VCO;
a multi-modulus prescaler to receive said output signal of said VCO and to divide a frequency of said output signal by a variable divisor value to generate a comparison signal; and
a programmable digital signal processor (DSP) to compare a phase of said comparison signal to a phase of a reference signal and to generate an output signal based on said comparison.

12. The communication device of claim 11, wherein:
said programmable DSP is to generate a control signal for said multi-modulus prescaler to control said variable divisor value.

13. The communication device of claim 11, wherein:
said programmable DSP is to perform noise shaping during generation of said control signal for said multi-modulus prescaler to move spurious frequencies away from said output frequency of said VCO.

14. The communication device of claim 11, wherein:
said programmable DSP includes a program memory and sequencer to store program instructions and to sequence through the instructions.

15. The communication device of claim 14, wherein:
said programmable DSP includes a multi-functional DSP datapath to process data in a desired manner, said multi-functional DSP datapath to receive control information from said program memory and sequencer to control the operation thereof.

16. The communication device of claim 11, wherein:
said programmable DSP is to provide modulation to said VCO to generate an appropriate phase for a signal to be transmitted from the at least one antenna.

17. The communication device of claim 16, wherein:
said programmable DSP is to pre-distort said modulation to compensate for a frequency response of said phase locked loop.

18. The communication device of claim 16, wherein:
said programmable DSP is to provide pre-emphasis filtering to said modulation to compensate for a frequency response of said power amplifier.

19. A method comprising:
comparing, within a digital signal processor (DSP), a phase of a comparison signal to a phase of a reference signal in a phase locked loop (PLL); and
developing an input signal for a loop filter in said PLL, using said DSP, based on said comparison.

20. The method of claim 19, wherein:
developing an input signal includes generating an input signal for a charge pump within said DSP, said charge pump being coupled to an input of said loop filter.

21. The method of claim 20, wherein:
developing an input signal includes generating a pulse width modulation (PWM) signal within said DSP to be applied directly to an input of said loop filter.

22. The method of claim 19, further comprising:
generating said comparison signal within said DSP using an output signal of a VCO in said PLL, before comparing.

23. The method of claim 19, further comprising:
receiving said comparison signal at said DSP from a multi-modulus prescaler in said PLL, before comparing.

24. The method of claim 23, further comprising:
generating a control signal for said multi-modulus prescaler to control a frequency divisor value thereof, within said DSP.

25. The method of claim 24, wherein:
generating a control signal includes performing noise shaping within said DSP to move spurious noise frequencies away from an output frequency of said PLL.

26. The method of claim 25, wherein:
performing noise shaping includes performing sigma-delta modulation within said DSP.

27. The method of claim 19, further comprising:
generating a control signal for said loop filter, within said DSP, to adjust a bandwidth of said loop filter.

28. The method of claim 19, wherein:
said PLL is coupled at an output to a power amplifier that drives at least one transmit antenna; and
said method further comprises performing direct transmit modulation within said DSP to modulate an output signal of said PLL with a required phase of a signal to be transmitted from said at least one antenna.

29. The method of claim 28, wherein:
performing direct transmit modulation includes pre-distorting said modulation, within said DSP, to compensate for a loop frequency response.

30. The method of claim 28, wherein:
performing direct transmit modulation includes pre-emphasis filtering said modulation, within said DSP, to compensate for a frequency response of said power amplifier.

31. An article comprising a storage medium having instructions stored thereon that, when executed by a computing platform, operate to:
compare a phase of a comparison signal to a phase of a reference signal in a phase locked loop (PLL); and
develop an input signal for a loop filter in said PLL based on said comparison.

32. The article of claim 31, wherein said instructions further operate to:
receive said comparison signal from a multi-modulus prescaler in said PLL.

33. The article of claim 32, wherein said instructions further operate to:
generate a control signal for said multi-modulus prescaler to control a frequency divisor value thereof.

34. The article of claim 33, wherein:
operation to generate a control signal includes operation to perform noise shaping to move spurious noise frequencies away from an output frequency of said PLL.

35. The article of claim 31, wherein said instructions further operate to:
generate a control signal for a loop filter within said PLL to adjust a bandwidth of said loop filter.

36. The article of claim 31, wherein:
said computing platform includes a programmable digital signal processor (DSP).
